(19) United States
(12) Patent Application Publication
(10) Pub. No.: US 2015/0378230 A1
(43) Pub. Date: Dec. 31, 2015

(54) Method of Pre-Attaching Assemblies to an Electrochromic Glazing for Accurate Fit or Registration After Installation

(71) Applicant: SAGE Electrochromics, Inc., Faribault, MN (US)

(72) Inventors: Kyle Gudmunson, Minneapolis, MN (US); Micah Somers, Minneapolis, MN (US); Brian Clemens, Burnsville, MN (US)

(21) Appl. No.: 14/743,503

(22) Filed: Jun. 18, 2015

Related U.S. Application Data
(60) Provisional application No. 62/016,927, filed on Jun. 25, 2014.

(51) Int. Cl. G02F 1/153; H02S 20/20; H01L 31/042

(52) U.S. Cl. CPC G02F 1/153; H01L 31/042; H02S 20/20

(57) ABSTRACT

A device and method of pre-attaching assemblies to glazing can provide for accurate fit or registration after installation. A solar panel provides power to an insulated glass unit. Mounting brackets are secured to the insulated glass unit. A plate adjustably attaches to the mounting brackets. After positioning the plate on the mounting brackets a solar panel is attached to the plate and the insulated glass unit is installed in a frame. The plate is adapted to be moved toward the frame such that the solar panel is flush to the frame after moving the plate. Trim pieces can then be installed over the portions of the plate not covered by the solar panel.

### CROSS-REFERENCE TO RELATED APPLICATION

The current application claims priority from U.S. Provisional Patent Application No. 62/016,927, filed Jun. 25, 2014, entitled “Method of Pre-Attaching Assemblies to an Electrochromatic Glazing for Accurate Fit or Registration After Installation,” naming as inventors Kyle Gudmunson et al., which is incorporated by reference herein in its entirety.

### BACKGROUND

Electrochromic glazings include electrochromic materials that are known to change their optical properties, such as coloration, in response to the application of an electrical potential, thereby making the device more or less transparent or more or less reflective. Typical prior art electrochromic devices include a counter electrode layer, an electrochromic material layer which is deposited substantially parallel to the counter electrode layer, and an ionically conductive layer separating the counter electrode layer from the electrochromic layer respectively, which is incorporated into an insulating glass unit (IGU). In addition, two transparent conductive layers are substantially parallel to and in contact with the counter electrode layer and the electrochromic layer.

Materials for making the counter electrode layer, the electrochromic material layer, the ionically conductive layer and the conductive layers are known and described, for example, in United States Patent Publication No. 2008/0169185, incorporated by reference herein, and desirably are substantially transparent oxides or nitrides. When an electrical potential is applied across the layered structure of the electrochromic device, such as by connecting the respective conductive layers to a low voltage electrical source, ions, such as Li⁺ ions stored in the counter electrode layer, flow from the counter electrode layer, through the ion conductor layer and to the electrochromic layer.

In addition, electrons flow from the counter electrode layer, around an external circuit including a low voltage electrical source, to the electrochromic layer so as to maintain charge neutrality in the counter electrode layer and the electrochromic layer. The transfer of ions and electrons to the electrochromic layer causes the optical characteristics of the electrochromic layer, and optionally the counter electrode layer in a complementary EC device, to change, thereby changing the coloration and, thus, the transparency of the electrochromic device.

It is possible to use a solar panel mounted to the IGU as the low voltage electrical source. When installing electrochromic glazings, attaching a solar panel to the IGU may require the installer to clean the glass, attach cables to the solar panel, install strips of tape, and manually locate and attach the solar panel to be flush with the frame. The tolerances in window framing systems, it is believed, make it difficult to pre-attach components to an IGU and have those components be flush to the frame. Therefore, a need exists for an improved device and method of pre-attaching assemblies to a glazing or IGU to provide an accurate fit after installation.

### BRIEF SUMMARY

An electrochromic assembly according to one aspect of the disclosure includes an IGU, a plate, and a solar panel. In one embodiment, the plate can be movably coupled to the IGU and the solar panel can be fastened to the plate. In one embodiment, at least one mounting bracket may be used to couple the plate to the IGU. In one embodiment, the solar panel may be electrically connected to the IGU. In one embodiment, the mounting bracket can provide the electrical connection between the solar panel and IGU. In other embodiments, a flexible circuit, e.g., a polyimide flexible circuit, can provide the electrical connection between the solar panel and IGU.

A method of installing an electrochromic assembly according to another aspect of the disclosure includes coupling a plate to an IGU, securing a solar panel to the plate, and installing the IGU in a frame. The method can further include the steps of fixing mounting brackets to the IGU, adhering the plate to the mounting bracket, or both fixing and adhering. In some embodiments, the solar panel and plate may remain free to move relative to the IGU after installation.

A method of providing an electrochromic assembly may include providing an electrical connection between the solar panel and the IGU. The electrical connection according to one aspect of the disclosure could be a polyimide flexible circuit or the mounting bracket. Providing an electrochromic assembly can also include installing the IGU in a frame and advancing the plate and solar panel toward the frame until the solar panel is flush with the frame. Trim may be provided which can be installed on the plate adjacent to the solar panel.

### BRIEF DESCRIPTION OF THE DRAWINGS

Embodiments are illustrated by way of example and are not limited in the accompanying figures.

FIG. 1 shows a fully assembled electrochromic assembly according to an embodiment.

FIG. 2 is an isolated view of an IGU according to an embodiment.

FIG. 3A, 3B, and 3C show a close-up perspective, top, and front view, respectively, of the mounting brackets of FIG. 2.

FIG. 4 shows the IGU of FIG. 2 with a plate attached.

FIG. 5 is a close-up view of the plate of FIG. 4.

FIG. 6 shows the IGU of FIG. 4 with a solar panel attached to the plate.

FIG. 7 is a side view of the IGU of FIG. 6 in cross-section.

FIG. 8 shows the IGU of FIG. 6 in a frame.

FIG. 9 shows the IGU of FIG. 8 after adjusting the position of the plate.

FIG. 10 is a flow chart depicting a method of installing an electrochromic device.

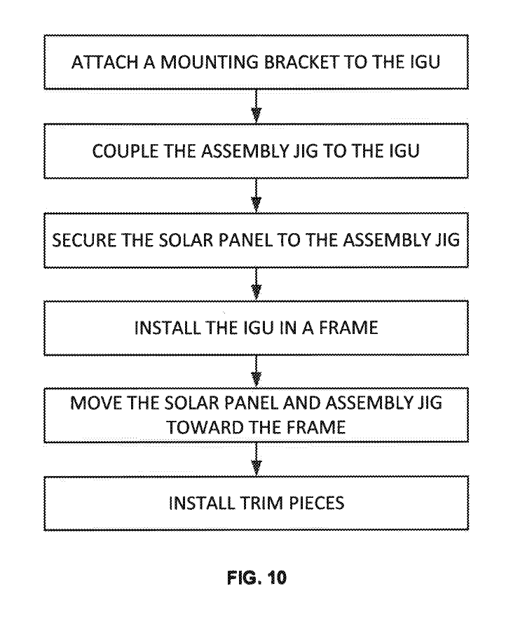

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the electrochromic, window, and glazing arts.

Although the invention disclosed in this application has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended exemplary claims.

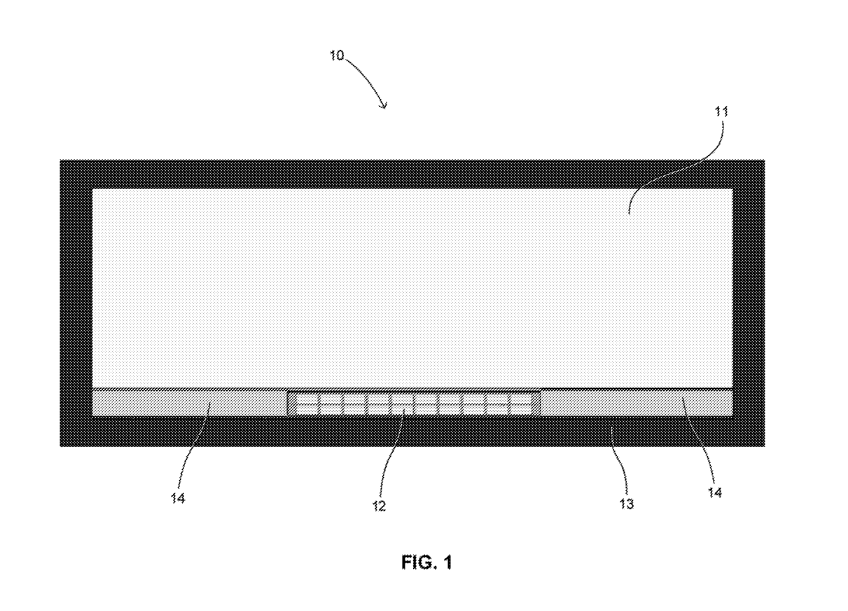

In one embodiment, illustrated in FIGS. 1-9, an electrochromic (EC) assembly 10 includes an IGU 11, a solar panel 12, a frame 13, and trim 14. As will be discussed more fully herein, the EC assembly 10 is designed to allow a solar panel to be adjusted after installation to abut a frame.

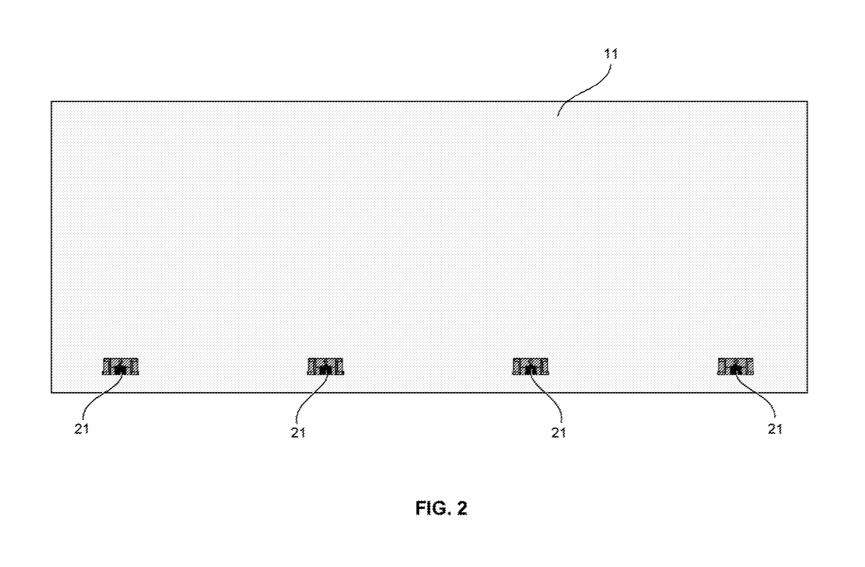

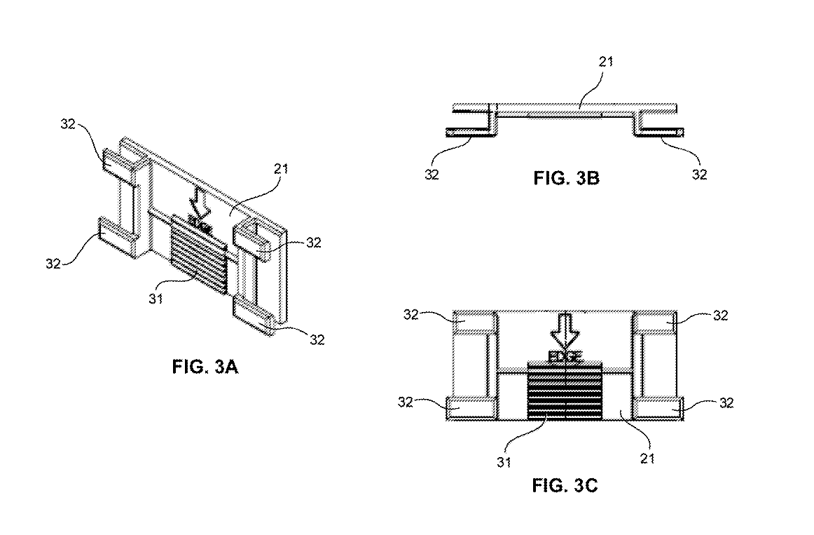

FIG. 2 details an embodiment of an IGU 11. As shown, IGU 11 has brackets 21 attached to it. Brackets 21 can be secured to the IGU 11 using traditional attachment devices (e.g., glue, screws, double sided tape, and nut and bolt assemblies) or molded into the glass during its formation. In some embodiments, the brackets can provide an electrical connection between a solar panel and an EC layer. FIG. 3 shows a closer view of bracket 21. In the embodiment shown, the bracket 21 includes arms 32 that extend away from the IGU 11. The arms 32 secure the plate to the IGU. The bracket 21 also includes a movement limiter to maintain the position of plate 41. As shown, the movement limiter is formed by teeth 31 on the bracket 21, although other embodiments are also envisioned. In a particular embodiment, the bracket has 8 teeth to 13 teeth with a height of 0.75 mm per tooth to 1.875 mm per tooth.

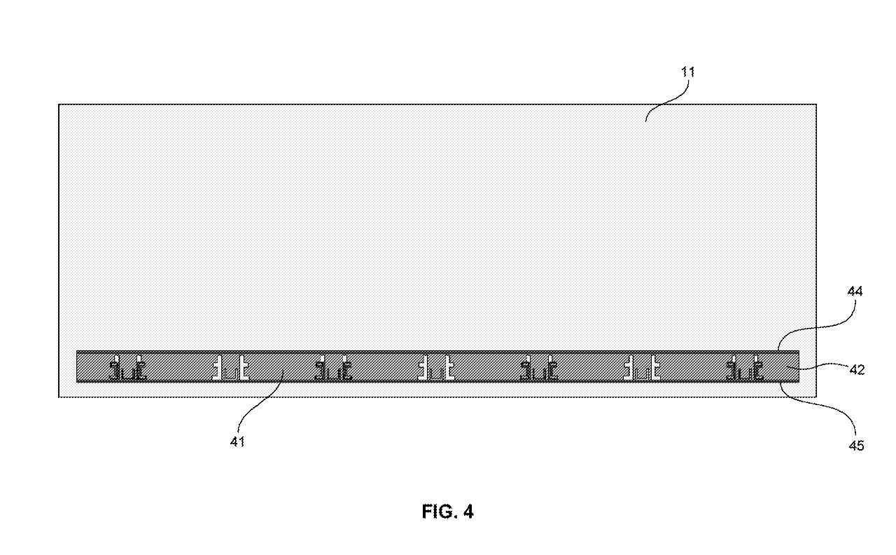

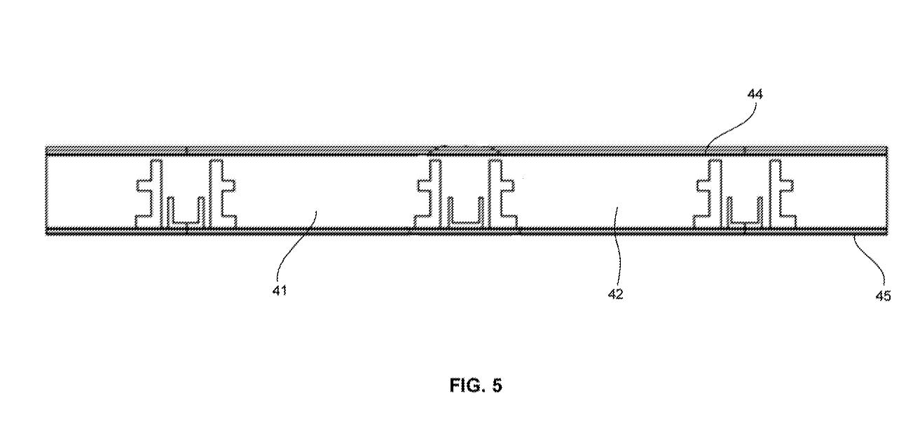

FIGS. 4 and 5 show a plate 41 coupled to the IGU 11. The plate 41 can be mounted on the brackets 21. As shown, the face 42 of plate 41 has holes 43 which allow the arms 32 of the bracket to pass through. As the plate 41 is adjusted, the holes 43 and arms 32 become misaligned, allowing the arms to reduce the likelihood or prevent the plate from moving away from the bracket. In other embodiments, the plate can have appendages to exert a force on edges of a solar panel 12 to frictionally hold the solar panel in place. In embodiments where the bracket will serve as the electrical connection between the solar panel and EC layer, the plate 41 can have openings extending through it to allow wires or a polyimide flexible circuit to connect the solar panel to the bracket, or the plate 41 may be adapted to provide the electrical connection between the solar panel and EC layer. For example, the arms 32 can be composed, at least partially, of an electrically conductive material such that electrical energy can transfer from the solar panel to the IGU, although other methods are also contemplated. In other embodiments, the electrical connection may extend between a trim piece and the plate to an edge of the IGU. As shown, the plate 41 extends across a majority of the glass 11 and attaches to multiple brackets 21. In other embodiments, more than one plate may be utilized or a plate may connect to as little as only one bracket, provided that the desired fit of the solar panel to a frame is achieved and the bracket has sufficient strength to maintain the position of the plate.

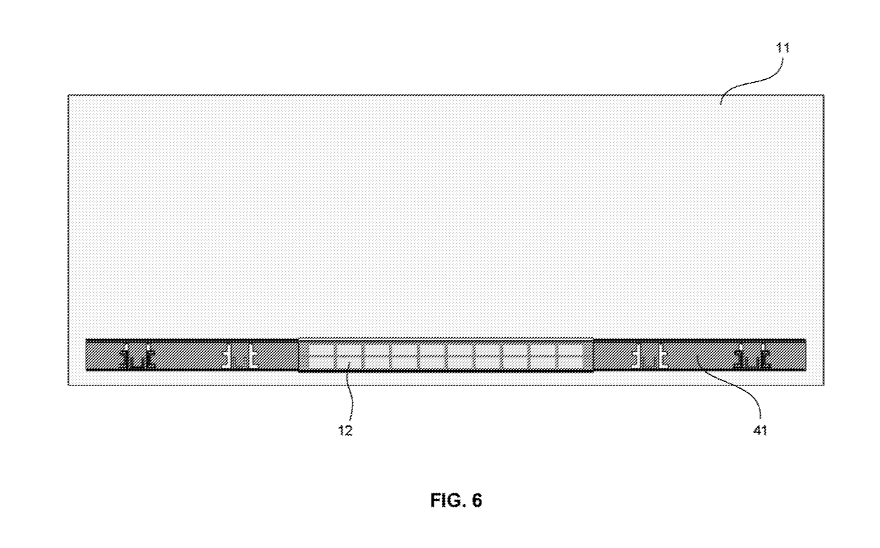

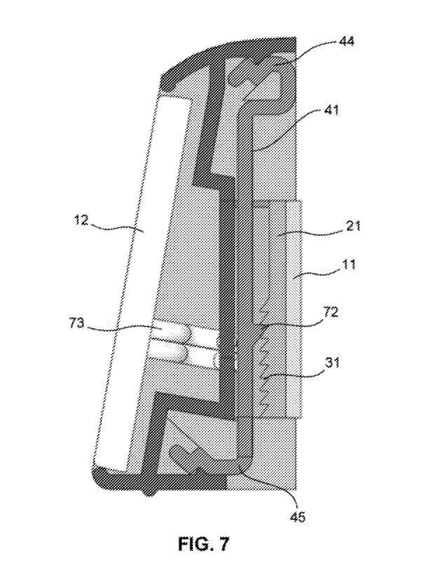

FIG. 6 shows a solar panel 12 attached to the plate 41. The solar panel may be any make and model in accordance with the specification. One such solar panel contemplated is manufactured by China Solar LTD, model number KS-M33057G. FIG. 7 shows a sectional view of the solar panel 12 attached to the plate 41 shown in FIG. 6. The bracket 21 is attached to the IGU 11 using methods previously described. As shown, a pawl 72 extends from the plate 41 toward the teeth 31 of bracket 21 to prevent movement of the plate 21 in the direction of a top lip 44, while allowing some movement in the direction of a bottom lip 45. Although the movement limiter is depicted as a pawl and tooth structure, other embodiments are also possible, for example, a ball and detent. In the embodiment shown, the solar panel 12 attached to the plate 41 via double sided tape (e.g., VHB™-brand tape manufactured by 3M). However, other methods of attachment are also possible (e.g., glue, nut and bolt assemblies, rivets, welding). In other embodiments, appendages can extend over the top lip 44 and bottom lip 45 of the plate 41 to secure the solar panel 12 to the plate 41. The appendages provide a releasable connection to the plate 41. In this way, the solar panel can be removed for replacement, repairs, or the like, as necessary. As shown, a polyimide flexible circuit 73 extends from an edge of the solar panel 12 facing the plate 41. As previously discussed, the polyimide flexible circuit 73 can provide the electrical connection to the EC layer.

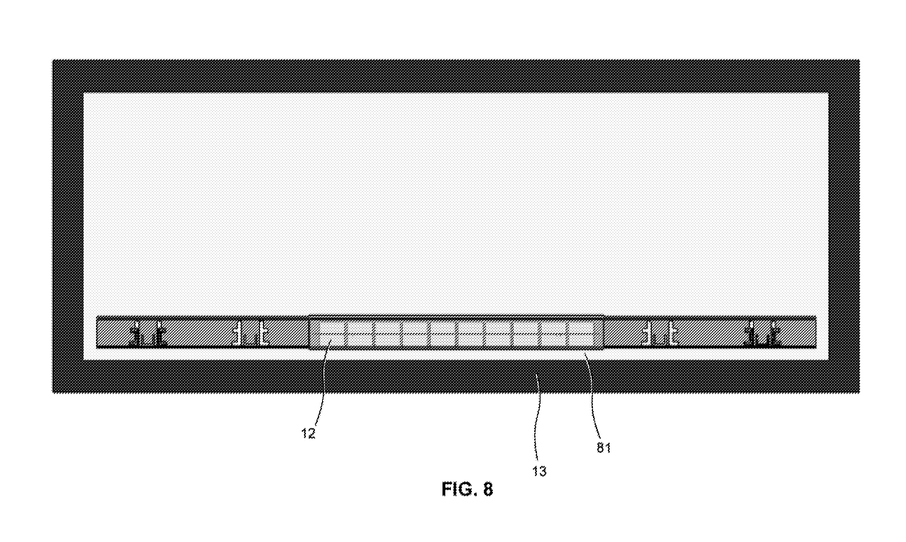

FIG. 8 depicts the IGU 11 with the plate 41 and solar panel 12 installed in a frame 13. As shown, a space 81 exists between the solar panel 12 and frame 13 when the glass is first installed in the frame. The space 81 compensates for varying tolerances associated with window framing systems. In some embodiments, the IGU 11 may be supplied with the plate 41 and solar panel 12 attached. In other embodiments the solar panel and/or plate may be supplied separately and attached after the glass is installed in the frame.

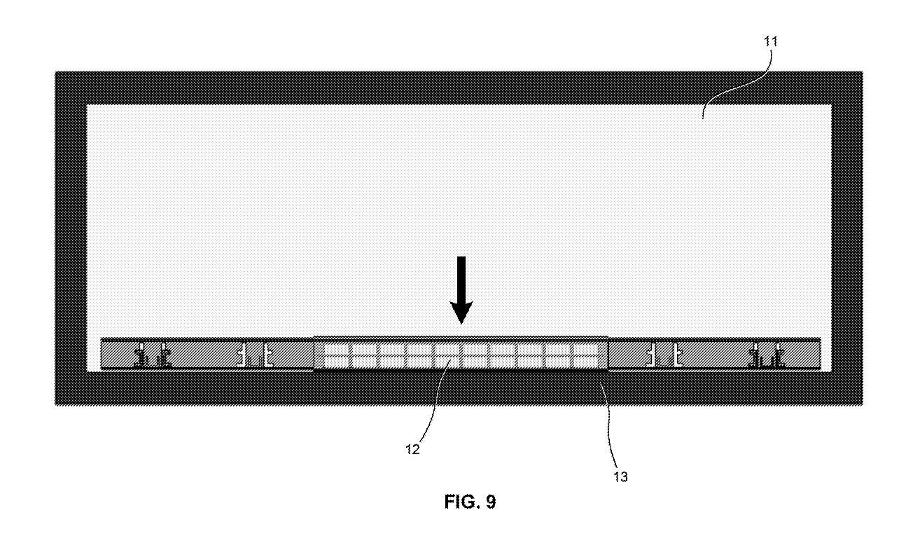

After the glass 11 is installed in the frame 13, a force of about 2 pounds (0.9 kg) to about 7 pounds (3.2 kg) can be exerted on the solar panel 12 and/or plate 41 in the direction of the arrow shown in FIG. 9. The plate 41 can be moved by manually appling force such as an installer pushing on the top lip 44 of the plate 41. However, a clamp or similar tool could also be used to move the plate 41. As the solar panel 12 and plate 41 move towards the frame 13, the space 81 is lessened or eliminated leaving the solar panel 12 flush or nearly flush with the frame 13. As the plate 41 moves toward the frame 13, in one embodiment, the pawl 72 advances along the teeth 31 which prevents the plate 41 from reverting to its original position after it has been adjusted. In some embodiments, the plate is flexible to allow varying degrees of movement along the jig to accommodate fluctuations in the frame. Once the plate 41 and solar panel 12 are in the final position, trim 14 can be installed on the portions of the plate 41 not covered by the solar panel 12 for an aesthetically pleasing installation as shown in FIG. 1. Many different aspects and embodiments are possible. Some of those aspects and embodiments are described below. After reading this specification, skilled artisans will appreciate that those aspects and embodiments are only illustrative and do not limit the scope of the present invention. Exemplary embodiments may be in accordance with any one or more of the ones as listed below.

### Embodiment 1

An electrochromic assembly comprising:

an insulated glass unit;

a plate; and

a solar panel;

wherein the plate is movably coupled to the insulated glass unit and the solar panel is fastened to the plate.

### Embodiment 2

The electrochromic assembly of Embodiment 1, further comprising at least one mounting bracket coupling the insulated glass unit to the plate.

### Embodiment 3

The electrochromic assembly of Embodiment 1, wherein the solar panel is electrically connected to the insulated glass unit.

### Embodiment 4

The electrochromic assembly of Embodiment 3, wherein the mounting bracket comprises the electrical connection between the solar panel and the insulated glass unit.

### Embodiment 5

The electrochromic assembly of Embodiment 3, further comprising a flexible circuit as the electrical connection between the solar panel and the insulated glass unit.

### Embodiment 6

The electrochromic assembly of Embodiment 2, wherein the mounting bracket comprises a movement limiter.

### Embodiment 7

The electrochromic assembly of Embodiment 6, wherein the movement limiter comprises a pawl and tooth structure.

### Embodiment 8

A method of installing an electrochromic assembly comprising:

coupling a plate to an insulated glass unit;

securing a solar panel to the plate; and

installing the insulated glass unit in a frame.

### Embodiment 9

The method of Embodiment 8, wherein coupling the plate to the insulated glass unit further comprises fixing at least one mounting bracket to the insulated glass unit and adhering the plate to the mounting bracket.

### Embodiment 10

The method of Embodiment 8, wherein the solar panel and plate are movable relative to the insulated glass unit.

### Embodiment 11

The method of Embodiment 8, further comprising electrically connecting the solar panel to the insulated glass unit.

### Embodiment 12

The method of Embodiment 11, wherein a flexible circuit comprises the electrical connection between the solar panel and insulated glass unit.

### Embodiment 13

The method of Embodiment 8, further comprising advancing the plate and solar panel toward the frame in a first direction until the solar panel is flush with the frame.

### Embodiment 14

The method of Embodiment 12, wherein the mounting bracket comprises a movement limiter to prevent movement of the plate in a second direction.

### Embodiment 15

The method of Embodiment 14, further comprising attaching trim to the plate.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electrochromic assembly comprising:
an insulated glass unit;
a plate; and
a solar panel;
wherein the plate is movably coupled to the insulated glass unit and the solar panel is fastened to the plate.

2. The electrochromic assembly of claim 1, further comprising at least one mounting bracket coupling the insulated glass unit to the plate.

3. The electrochromic assembly of claim 1, wherein the solar panel is electrically connected to the insulated glass unit.

4. The electrochromic assembly of claim 3, wherein the mounting bracket comprises the electrical connection between the solar panel and the insulated glass unit.

5. The electrochromic assembly of claim 3, further comprising a flexible circuit as the electrical connection between the solar panel and the insulated glass unit.

6. The electrochromic assembly of claim 2, wherein the mounting bracket comprises a movement limiter.

7. The electrochromic assembly of claim 6, wherein the movement limiter comprises a pawl and tooth structure.

8. A method of installing an electrochromic assembly comprising:
coupling a plate to an insulated glass unit;
securing a solar panel to the plate; and
installing the insulated glass unit in a frame.

9. The method of claim 8, wherein coupling the plate to the insulated glass unit further comprises fixing at least one mounting bracket to the insulated glass unit and adhering the plate to the mounting bracket.

10. The method of claim 8, wherein the solar panel and plate are movable relative to the insulated glass unit.

11. The method of claim 8, further comprising electrically connecting the solar panel to the insulated glass unit.

12. The method of claim 11, wherein a flexible circuit comprises the electrical connection between the solar panel and insulated glass unit.

13. The method of claim 8, further comprising advancing the plate and solar panel toward the frame in a first direction until the solar panel is flush with the frame.

14. The method of claim 12, wherein the mounting bracket comprises a movement limiter to prevent movement of the plate in a second direction.

15. The method of claim 14, further comprising attaching trim to the plate.
